(19) United States
(12) Patent Application Publication
(10) Pub. No.: US 2014/0254101 A1
(43) Pub. Date: Sep. 11, 2014

(54) SMART PHONE ON A CHIP AND METHOD MAKING SAME

(71) Applicant: QUALCOMM INCORPORATED, San Diego, CA (US)

(72) Inventors: Mark A. CARTER, San Diego, CA (US); Yang ZHANG, San Diego, CA (US); Yongsheng PENG, San Diego, CA (US); Jack B. STEENSTRA, San Diego, CA (US); Michael G. BARRETT, San Diego, CA (US)

(73) Assignee: QUALCOMM INCORPORATED, San Diego, CA (US)

(21) Appl. No.: 13/786,358

(22) Filed: Mar. 5, 2013

(51) Int. Cl. H05K 7/20; H05K 9/00; H05K 3/30

(52) U.S. Cl. CPC H05K 7/205; H05K 3/30; H05K 9/00
USPC 361/712; 29/832

(57) ABSTRACT

Method and apparatuses for making a smart phone on a chip (SPOC) are described. Active components may be embedded into a copper core. In an aspect, and optionally, passive components may also be embedded into the copper core. Printed circuit board (PCB) laminate may be layered above and below the copper core. A copper ground plane may be fixed underneath the layer of PCB laminate below, and furthest from, the copper core. One or more additional components may be surface mounted on top of the PCB laminate layers above the copper core. A conformal coating may be applied to completely and thinly encase the one or more surface mounted additional components. The conformal coating may include trenching and a copper sputter coating finish.

### BACKGROUND

I. Field

The following description relates generally to printed circuit boards and systems on a chip, and more particularly to a smart phone on a chip.

II. Background

An electrical device, such as a computing or communication device, typically includes a printed circuit board (PCB) having circuit components configured to enable the functionality of the electrical device. Such circuit components may be referred to as an integrated circuit, chip, or microchip, and may be mounted on the surface of the PCB. Such chips may be referred to as surface mount technology (SMT) components.

The use of SMT for mounting packaged semiconductor devices onto printed circuits boards is common. Surface mount packaging can provide for a thin profile end device, where the packaged semiconductor device may lay substantially flat on a thin board. In addition, consolidation and integration of multiple modules or devices into a single module such as a system-on-chip has been widely employed.

In cases where all components of a computer or other electronic system, such as a smart phone, wireless device, or terminal, are integrated into a single chip, the single chip may be referred to as a system on a chip. In general, system-on-chip, also known as system-on-a-chip, SoC, or SOC, normally refers to a chip that incorporates the necessary hardware and electronic circuits for a complete system. An SOC comprises, on a single chip, memory such as RAM (random access memory) or ROM (read-only memory), a microprocessor or microcontroller, interfaces for peripheral devices, control logic for data input and output, data converters and other components that are part of a complete computer system.

As the demand for more powerful wireless devices, such as smart phones and other access terminals used for wireless communications, has continued to grow, so too has the need for more powerful processors and larger batteries. This has pushed phone manufacturers to demand PCBs with a smaller footprint, which typically causes a strain on such a PCB in the form of increased heat and radio frequency (RF) interference. Some manufacturers have handled the problem by creating thicker PCBs that have, for example, 10 or more layers, in order to keep the printed circuit board footprint small. This solution has led to an increase in cost of the bill of materials.

Thus, an SOC having improvements in heat dissipation and decreased RF interference is desired.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In one aspect, a method for making a smart phone on a chip (SPOC) is described. The method may include embedding active components into a copper core. The method may include layering printed circuit board (PCB) laminate above and below the copper core. The method may include fixing a copper ground plane underneath the layer of PCB laminate below, and furthest from, the copper core. The method may include surface mounting one or more additional components on top of the PCB laminate layers above the copper core. The method may include applying a conformal coating to completely and thinly encase the one or more surface mounted additional components. The conformal coating may include trenching and a copper sputter coating finish.

In one aspect, a smart phone on a chip (SPOC) prepared by a method described herein is described.

In one aspect, a smart phone on a chip apparatus is described. The apparatus may include a copper ground plane. The apparatus may include a copper core. The apparatus may include one or more active components embedded in the copper core. The apparatus may include a first set of printed circuit board (PCB) laminate layers above the copper core. The apparatus may include a second set of printed circuit board (PCB) laminate layers below the copper core but above the copper ground plane. The apparatus may include one or more additional components surface mounted on top of the PCB laminate layer above, and furthest from, the copper core. The apparatus may include copper vias configured to conduct heat from the copper core through the first and second sets of PCB laminate layers to the top and bottom of the smart phone on a chip. The apparatus may include a shield comprising a conformal coating on top of the one or more additional surface-mounted components. The conformal coating may include trenching and copper sputter coating finish.

In one aspect, a computer program product for making a smart phone on a chip is described. The computer program product may include a computer-readable medium comprising code. The code may cause a computer to embed active components into a copper core. The code may cause a computer to layer printed circuit board (PCB) laminate above and below the copper core. The code may cause a computer to fix a copper ground plane underneath the layer of PCB laminate below, and furthest from, the copper core. The code may cause a computer to surface mount one or more additional components on top of the PCB laminate layers above the copper core. The code may cause a computer to apply a conformal coating to completely and thinly encase the one or more surface mounted additional components. The conformal coating may include trenching and a copper sputter coating finish.

In one aspect, a smart phone on a chip apparatus is described. The apparatus may include means for conducting heat from a copper core to dissipate heat out of the top and bottom of the smart phone on a chip. Active components may be embedded in the copper core. The apparatus may include means for layering above and below the copper core. One or more additional components may be surface-mounted to the layering means above the copper core. The apparatus may include means for shielding the one or more additional components. The shielding means may be a conformal coating including trenching and a copper sputter coating finish. The apparatus may include means for supporting the layering means below the copper core. The supporting means may be a copper ground plane.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is an illustration of an exemplary perspective view of a smart phone on a chip (SPOC), including hidden lines representing unseen edges and a cross-sectional plane;

FIG. 2 is a cross-sectional view along line 2-2 in FIG. 1 of the smart phone on a chip (SPOC);

FIG. 3 is an illustration of an exemplary exploded view of an aspect of a smart phone on a chip (SPOC); and

FIG. 4 is a flow chart of an exemplary method of an aspect of making a smart phone on a chip (SPOC).

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

In accordance with one or more aspects and corresponding disclosure thereof, various features are described in connection with providing a smart phone on a chip (SPOC). The described aspects may help to address issues of heat, interference, and size while simultaneously providing smaller printed circuit boards (PCB) for use in the new wireless devices of today's market. More particularly, a SPOC for use in wireless devices is described such that processing power is at a level necessary to meet the high demands of such wireless devices, while maintaining a small PCB footprint and minimizing issues, such as inability to dissipate heat, hot spots and interference. To meet this goal, the described SPOC combines embedding technology for both passive and active components, a copper core and copper ground plane, heat dissipating vias, and a conformal coating with a copper sputter coating finish. Each element of this combination works together to dissipate heat and reduce interference. The SPOC may be installed for use in an access terminal, such as a smart phone, tablet, machine-to-machine (M2M) product, or the like.

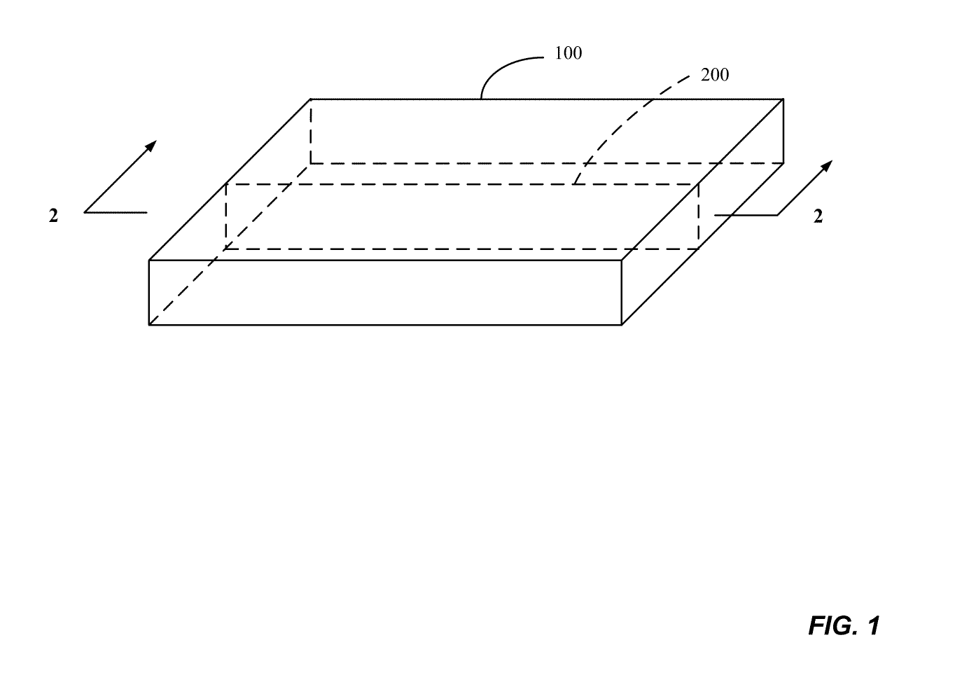

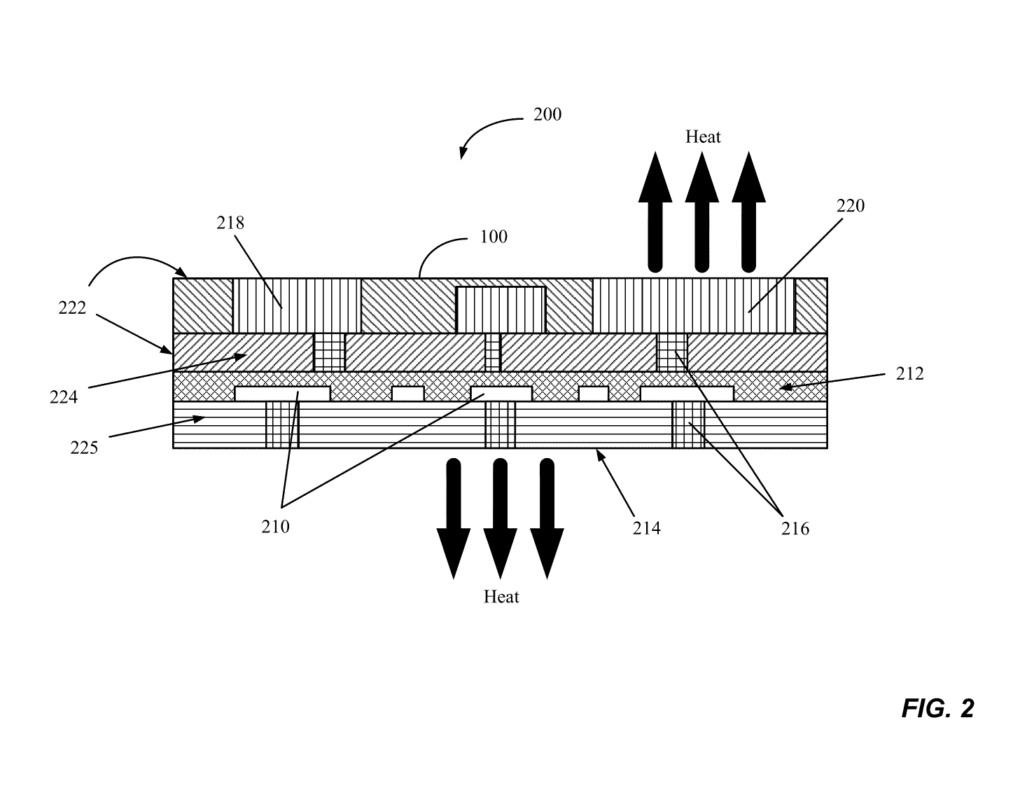

FIG. 1 is an illustration of an exemplary perspective view of a smart phone on a chip (SPOC) 100. To fully appreciate the described aspects of SPOC 100, a cross-section, identified by 200, may be taken along line 2-2 of FIG. 1, as shown in FIG. 2.

FIG. 2 is an illustration of an exemplary cross-sectional view of a smart phone on a chip (SPOC), such as SPOC 100. Embedding technology may be used to embed both passive components (not shown), such as resistors and capacitors, and active components 210, such as transistors, integrated circuits (ICs), and logic gates, into a copper core 212 of the SPOC. The copper core 212 serves as an embedding substrate, which provides thermal and electrical properties superior to non-embedding solutions, and superior to embedding solutions that use other materials (e.g., epoxies, silicones). Embedding both active and passive components in a copper core allows the copper core to dissipate heat and reduce hotspots in the SPOC 100. Providing for additional heat dissipation, relative to traditional structures, from the copper core is especially important when active components are embedded in the copper core. Active components may be larger, and send and receive more signals than passive components, and, as such, tend to create more heat than passive components. Embedding both active and passive components in the copper core also allows the SPOC 100 to include a large, flat ground plane 214, also made of copper. As described in greater detail below, the ground plane 214 may be below a layer of PCB laminate 225 mounted below the copper core 212.

Heat may be dissipated from the SPOC 100 through both the top and bottom of the SPOC 100. In an aspect, the copper core 212 includes heat-conducting copper vias 216 in PCB layers 225 and 224 to a top surface of the SPOC 100 and to the copper ground plane 214, which each allow heat to flow out of the top and bottom of the SPOC, respectively. As used here, the term “via” may include a heat conducting structure that extends through one or more layers of SPOC 100. Additionally, as described in greater detail below, in another aspect, a conformal coating with trenching and a copper sputter coating finish may be applied on top of surface-mount technology (SMT) components 218 and 220. The conformal coating with trenching and a copper sputter coating finish may be very thin, and, as such, may be in direct contact with the top of SMT components 218 and 220, which allows heat to dissipate directly from the SMT components 218 and 220 through the conformal coating and out the top of the SPOC 100.

Interference may be reduced on a PCB by isolating RF signals, digital signals, and processor functionality. Rather than using a traditional metal can or cap to create a Faraday cage (also called a Faraday or RF shield) for interference reduction, in an aspect, a conformal coating material may be used to cut trenches and compartmentalize the SPOC 100 and isolate components from one another, thus reducing interference. The described conformal coating material may be formed by applying an insulating molded material to the surface of a layer of PCB laminate, such as, for example, the top layer of PCB laminate 224, on which the SMT components 218 and 220 have been placed, scribing compartments into the mold material, and applying a thin layer of conductive material, such as copper sputter coating finish to the resulting surface area. This structure shields the components from one another and the external environment, which may lower interference. The resulting copper compartments respectively function as a shield 222. Such scribed compartments also may be referred to as shielded, or shielding, areas or shielded, or shielding, compartments. In an aspect, when the conformal coating material is applied in a very thin layer to just cover the SMT components 218 and 220 in each of the X, Y, and Z dimensions, the resulting shield 222 is much thinner, and takes up much less space, than a traditional metal can cage. In other words, because the coating is so thin, the dimensions of the shield 222 may not be much larger than the dimensions of the components, which helps provide SPOC 100 with a relatively small footprint and a relatively thin profile, e.g., only as tall as the tallest component.

In one aspect, the conformal coating material may have a coefficient of thermal expansion that is similar to, or within an acceptable range of, a coefficient of thermal expansion for the SMT components 218 and 220, as well as PCB laminate layers 225 and 224, of the SPOC 100. For example, the acceptable range is a range of values sufficient to avoid warping and other undesirable effects on the SPOC during the heating processes performed during one or more of the conformal coating process and the surface mounting process, and/or other manufacturing stages.

In one aspect, compartmentalizing the SPOC may allow for the use of the same basic Faraday cage principle in a variety of different ways so that a product line can use the same conformal coating technique, and then superimpose the compartmentalization after completion of the conformal coating process. This may allow for design and cost reduction in the shielding process, especially as applied to different but similar product lines. Additionally, the described compartments that define respective Faraday cages may provide additional physical robustness to the product, such that it may have better stiffness properties, which may help protect the surface mounted components from the external environment.

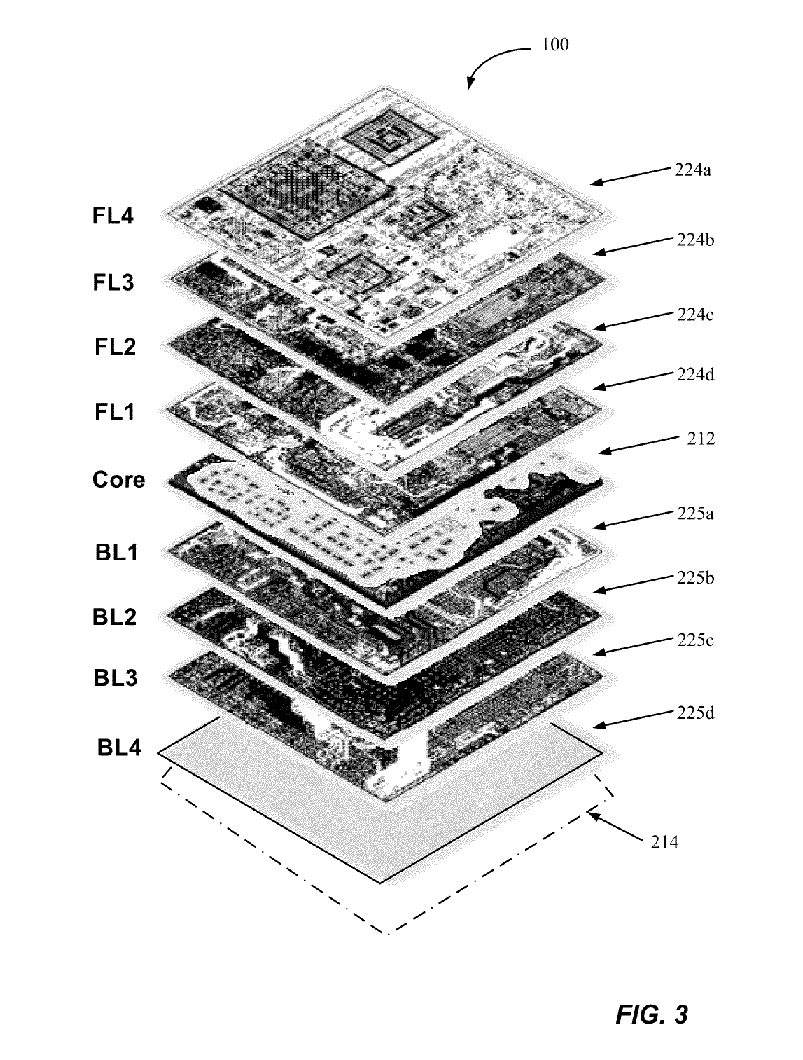

FIG. 3 is an illustration of an exemplary exploded view of a smart phone on a chip (SPOC), such as SPOC 100. Copper core 212 is shown in the middle of a series of PCB layers, such as PCB layers 224 of FIG. 2, above the copper core 212, and PCB layers, such as PCB layers 225 of FIG. 2, below the copper core. In the example of FIG. 3, four PCB layers are shown above the copper core 212: layers 224a, 224b, 224c, and 224d. However, it is understood that any number of layers may be applied above the copper core 212. Similarly, in the example of FIG. 3, four PCB layers are shown below the copper core 212: layers 225a, 225b, 225c, and 225d. Again, it is understood that any number of layers may be applied below the copper core 212. The copper ground plane 214, is shown below the PCB layer 225d, which is the bottom-most PCB layer underneath copper core 212.

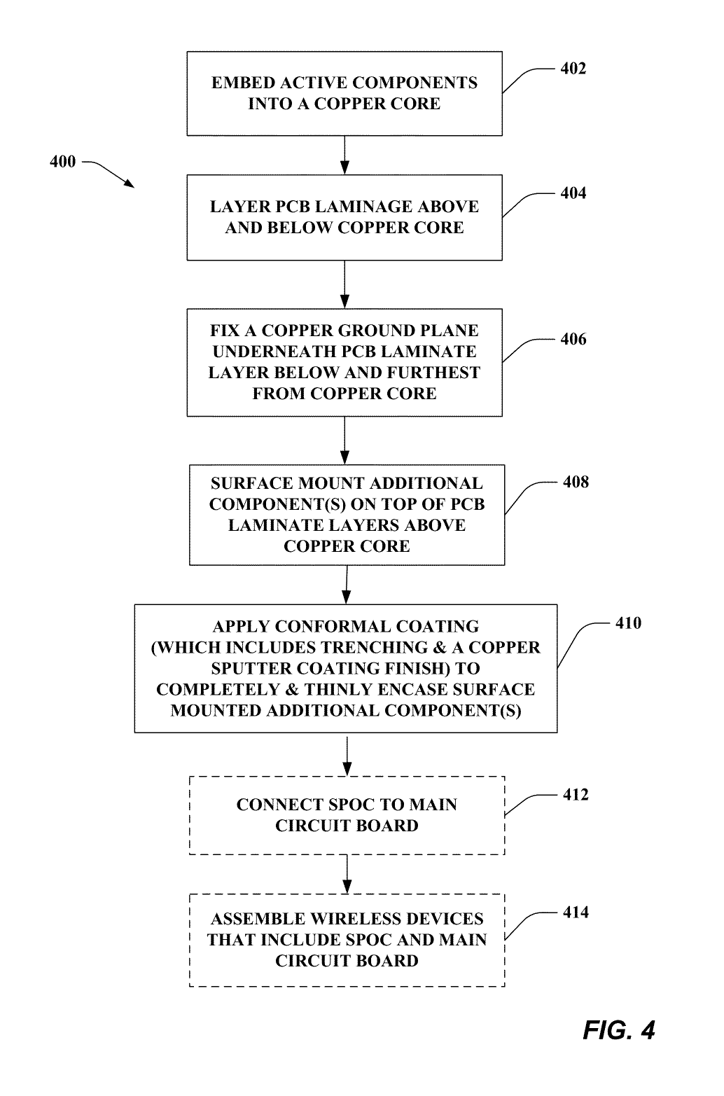

FIG. 4 is an illustration of an exemplary method 400 of making a smart phone on a chip (SPOC), such as SPOC 100. As shown at 402, method 400 may include embedding active components into a copper core. In one example, a circuit board with a copper core, such as copper core 212 of FIGS. 2 and 3 may be created. Slots may be cut into the copper core 412 to embed various components, such as embedded active components 210 of FIG. 2. In an aspect, and for example, passive components also may be embedded into a copper core, such as copper core 212 of FIGS. 2 and 3.

The method 400 may include layering PCB laminate above and below the copper core, as shown at 404. For example, several layers of PCB laminate, such as PCB laminate layers 225 and 224, may be built below, and on top of, a copper core, such as copper core 212, respectively. In one aspect, and for example, four layers of PCB laminate may be built above and below the copper core as shown in FIG. 3.

As shown at 406, the method 400 may include fixing a copper ground plane underneath the PCB laminate layer below, and furthest from, the copper core. For example, a copper ground plane 214 may be fixed below the bottom-most layer of PCB laminate 225 below the copper core. The copper core 212 may conduct heat to the copper ground plane through copper vias to dissipate heat out of the bottom of the SPOC. In one example, the method 400 may optionally (not shown) include testing and validating RF channels and signals of the PCB laminate layers and copper core (which together may be referred to generally as a “product”) upon fixing the copper ground plane.

As shown at 408, the method 400 may include surface-mounting one or more additional components on top of the PCB laminate layers above the copper core. For example, additional SMT components, such as SMT components 218 and 220 of FIG. 2, may be surface-mounted to the product. The additional SMT components may conduct heat through the conformal coating and copper sputter coating finish to dissipate heat out of the top of the SPOC. The method 400 may optionally (not shown) also include additional testing and software validation once the additional SMT components are mounted to the product.

The method 400 may include applying a conformal coating to completely and thinly encase the one or more surface mounted additional components, as shown at 410. The conformal coating may include trenching and a copper sputter coating finish. The conformal coating may be applied to the additional SMT components, such as SMT components 218 and 220, such that the conformal coating does not rise above the PCB laminate layers above the copper core more than the height of the tallest SMT component. In one example, the conformal coating may be applied to compartmentalize the one or more surface mounted additional components in order to isolate the components from one another to reduce interference. In one example, such a conformal coating process may include laser etching the product to create trenches.

In another example, a coefficient of thermal expansion associated with the conformal coating may be similar to, or within a certain range of, a coefficient of thermal expansion for the SMT components 218 and 220, as well as PCB laminate layers 225 and 224, in order to prevent warping or other issues during any heating stages of the manufacturing process.

In another example, several SPOCs may be created on a single panel, such that, for example, components of method 400 may be completed for each of a number of SPOCs on a single panel. In this case, the conformal coating process may, for example, include separating the individual SPOCs by, for example, splitting the panel into individual SPOCs or, in another example, removing each individual SPOC from the panel. The conformal coating process also may include, for example, cutting trenches and/or coating the product with copper sputter coating finish to create a copper shield, such as shield 222 of FIG. 2.

At 412, the method 400 may optionally include connecting the SPOC 100 to a main circuit board, and, at 414, optionally assembling wireless devices, such as, for example, smart phones, tablets, machine-to-machine (M2M) products, or the like, that include the SPOC 100 and the main circuit board.

In one aspect, and for example, the method 400 may be performed by a computer executing code to control other computers, devices, apparatuses, or machines to perform various aspects of the method 400 in the process of making a smart phone on a chip (SPOC), such as SPOC 100.

Although method 400 is shown and described as a series of acts, it is to be understood and appreciated that the methodologies are not limited by the order of acts, as some acts may, in accordance with one or more aspects, occur in different orders and/or concurrently with other acts from that shown and described herein. For example, it is to be appreciated that a methodology could alternatively be represented as a series of interrelated states or events, such as in a state diagram. Moreover, not all illustrated acts may be required to implement a methodology in accordance with one or more aspects.

As used in this application, the terms “component,” “module,” “system” and the like are intended to include a computer-related entity, such as but not limited to hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

Furthermore, various aspects are described herein in connection with a terminal, which can be a wired terminal or a wireless terminal A terminal can also be called a system, device, subscriber unit, subscriber station, mobile station, mobile, mobile device, remote station, remote terminal, access terminal, user terminal, terminal, communication device, user agent, user device, or user equipment (UE). A wireless terminal may be a cellular telephone, a satellite phone, a cordless telephone, a Session Initiation Protocol (SIP) phone, a wireless local loop (WLL) station, a personal digital assistant (PDA), a handheld device having wireless connection capability, a computing device, or other processing devices connected to a wireless modem. Moreover, various aspects are described herein in connection with a base station. A base station may be utilized for communicating with wireless terminal(s) and may also be referred to as an access point, a Node B, or some other terminology.

The techniques described herein may be used for creating a SPOC for use with various wireless communication systems such as CDMA, TDMA, FDMA, OFDMA, SC-FDMA and other systems. The terms “system” and “network” are often used interchangeably. A CDMA system may implement a radio technology such as Universal Terrestrial Radio Access (UTRA), cdma2000, etc. UTRA includes Wideband-CDMA (W-CDMA) and other variants of CDMA. Further, cdma2000 covers IS-2000, IS-95 and IS-856 standards. A TDMA system may implement a radio technology such as Global System for Mobile Communications (GSM). An OFDMA system may implement a radio technology such as Evolved UTRA (E-UTRA), Ultra Mobile Broadband (UMB), IEEE 802.11 (Wi-Fi), IEEE 802.16 (WiMAX), IEEE 802.20, Flash-OFDM, etc. UTRA and E-UTRA are part of Universal Mobile Telecommunication System (UMTS). 3GPP Long Term Evolution (LTE) is a release of UMTS that uses E-UTRA, which employs OFDMA on the downlink and SC-FDMA on the uplink. UTRA, E-UTRA, UMTS, LTE and GSM are described in documents from an organization named “3rd Generation Partnership Project” (3GPP). Additionally, cdma2000 and UMB are described in documents from an organization named “3rd Generation Partnership Project 2” (3GPP2). Further, such wireless communication systems may additionally include peer-to-peer (e.g., mobile-to-mobile) ad hoc network systems often using unpaired unlicensed spectrums, 802.xx wireless LAN, BLUETOOTH and any other short- or long-range, wireless communication techniques.

Various aspects or features will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

The various illustrative logics, logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Additionally, at least one processor may comprise one or more modules operable to perform one or more of the steps and/or actions described above.

Further, the steps and/or actions of a method or algorithm described in connection with the aspects disclosed herein may be embodied directly in hardware, in a software module executed by a processor, or in a combination of the two. A software module may reside in RAM memory, flash memory, ROM memory, EPROM memory, EEPROM memory, registers, a hard disk, a removable disk, a CD-ROM, or any other form of storage medium known in the art. An exemplary storage medium may be coupled to the processor, such that the processor can read information from, and write information to, the storage medium. In the alternative, the storage medium may be integral to the processor. Further, in some aspects, the processor and the storage medium may reside in an ASIC. Additionally, the ASIC may reside in a user terminal. In the alternative, the processor and the storage medium may reside as discrete components in a user terminal. Additionally, in some aspects, the steps and/or actions of a method or algorithm may reside as one or any combination or set of codes and/or instructions on a machine readable medium and/or computer readable medium, which may be incorporated into a computer program product.

In one or more aspects, the functions described may be implemented in hardware, software, firmware, or any combination thereof. If implemented in software, the functions may be stored or transmitted as one or more instructions or code on a computer-readable medium. Computer-readable media includes both computer storage media and communication media including any medium that facilitates transfer of a computer program from one place to another. A storage medium may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection may be termed a computer-readable medium. For example, if software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs usually reproduce data optically with lasers. Combinations of the above should also be included within the scope of computer-readable media.

While the foregoing disclosure discusses illustrative aspects and/or embodiments, it should be noted that various changes and modifications could be made herein without departing from the scope of the described aspects and/or embodiments as defined by the appended claims. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

What is claimed is:

1. A method of making a smart phone on a chip (SPOC), comprising:
embedding active components into a copper core;
layering printed circuit board (PCB) laminate above and below the copper core;
fixing a copper ground plane underneath the layer of PCB laminate at a position below, and furthest from, the copper core;
surface mounting one or more additional components on top of the PCB laminate layers above the copper core; and
applying a conformal coating to completely and thinly encase the one or more surface mounted additional components, wherein the conformal coating includes trenching and a copper sputter coating finish.

2. The method of claim 1, wherein applying a conformal coating to completely and thinly encase the one or more surface mounted additional components comprises cutting trenches and applying a conformal coating to compartmentalize the one or more surface mounted additional components.

3. The method of claim 2, wherein applying a conformal coating to compartmentalize the one or more surface mounted additional components comprises isolating the one or more surface mounted additional components from one another to reduce interference.

4. The method of claim 1, wherein a coefficient of thermal expansion for the conformal coating is within an acceptable range of a coefficient of thermal expansion for the one or more surface mounted additional components and PCB laminate layers above and below the copper core.

5. The method of claim 1, wherein the copper core conducts heat to the copper ground plane through copper vias to dissipate heat out of the bottom of the smart phone on a chip.

6. The method of claim 1, wherein the one or more surface mounted additional components conduct heat through the conformal coating and copper sputter coating finish to dissipate heat out of the top of the smart phone on a chip.

7. The method of claim 1, wherein applying a conformal coating to completely and thinly encase the one or more surface mounted additional components comprises applying a conformal coating that does not rise above the PCB laminate layers above the copper core more than the height of the tallest one or more surface mounted additional components.

8. The method of claim 1, further comprising embedding passive components in the copper core.

9. The method of claim 1, further comprising:
making more than one smart phone on a chip, comprising:
embedding a set of active components into one of multiple copper cores on a panel;
layering printed circuit board (PCB) laminate above and below each of the copper cores on the panel;
fixing a copper ground plane underneath the layer of PCB laminate below, and furthest from, each of the copper cores on the panel;
surface mounting one or more additional components on top of the PCB laminate layers above each of the copper cores on the panel; and
applying a conformal coating to completely and thinly encase the one or more surface mounted additional components on each of the copper cores, wherein the conformal coating includes trenching and a copper sputter coating finish.

10. The method of claim 9, further comprising embedding passive components into each of the copper cores on the panel.

11. The method of claim 1, further comprising
connecting the smart phone on a chip to a main circuit board; and
assembling wireless devices that include the smart phone on a chip and the main circuit board.

12. A smart phone on a chip (SPOC) prepared by the method of claim 1.

13. A smart phone on a chip apparatus, comprising:
a copper ground plane;
a copper core;
one or more active components embedded in the copper core;
a first set of printed circuit board (PCB) laminate layers above the copper core;
a second set of printed circuit board (PCB) laminate layers below the copper core but above the copper ground plane;
one or more additional components surface mounted on top of the PCB laminate layer above, and furthest from, the copper core;
copper vias configured to conduct heat from the copper core through the first and second sets of PCB laminate layers to the top and bottom of the smart phone on a chip; and
a shield comprising a conformal coating on top of the one or more additional surface-mounted components, wherein the conformal coating includes trenching and copper sputter coating finish.

14. The apparatus of claim 13, wherein the conformal coating is applied to completely and thinly encase the one or more surface mounted additional components to compartmentalize the one or more surface mounted additional components.

15. The apparatus of claim 14, wherein the one or more surface mounted additional components are isolated from one another to reduce interference.

16. The apparatus of claim 13, wherein a coefficient of thermal expansion for the conformal coating is within an acceptable range of a coefficient of thermal expansion for the one or more surface mounted additional components and PCB laminate layers above and below the copper core.

17. The apparatus of claim 13, wherein the copper core conducts heat to the copper ground plane through copper vias to dissipate heat out of the bottom of the smart phone on a chip.

18. The apparatus of claim 13, wherein the one or more surface mounted additional components conduct heat through the conformal coating and copper sputter coating finish to dissipate heat out of the top of the smart phone on a chip.

19. The apparatus of claim 13, wherein the conformal coating does not rise above the PCB laminate layers above the copper core more than the height of the tallest one or more surface mounted additional components.

20. The apparatus of claim 13, further comprising one or more passive components embedded in the copper core.

21. A computer program product for making a smart phone on a chip, comprising:
a computer-readable medium comprising:
code for causing a computer to:
embed active components into a copper core;
layer printed circuit board (PCB) laminate above and below the copper core;
fix a copper ground plane underneath the layer of PCB laminate below, and furthest from, the copper core;
surface mount one or more additional components on top of the PCB laminate layers above the copper core; and
apply a conformal coating to completely and thinly encase the one or more surface mounted additional components, wherein the conformal coating includes trenching and a copper sputter coating finish.

22. The computer program product of claim 21, wherein the code for causing a computer to apply a conformal coating to completely and thinly encase the one or more surface mounted additional components comprises code for causing a computer to cut trenches and apply a conformal coating to compartmentalize the one or more surface mounted additional components.

23. The computer program product of claim 22, wherein the code for causing a computer to apply a conformal coating to compartmentalize the one or more surface mounted additional components comprises code for causing a computer to isolate the one or more surface mounted additional components from one another to reduce interference.

24. The computer program product of claim 21, wherein a coefficient of thermal expansion for the conformal coating is within an acceptable range of a coefficient of thermal expansion for the one or more surface mounted additional components and PCB laminate layers above and below the copper core.

25. The computer program product of claim 21, wherein the copper core conducts heat to the copper ground plane through copper vias to dissipate heat out of the bottom of the smart phone on a chip.

26. The computer program product of claim 21, wherein the one or more surface mounted additional components conduct heat through the conformal coating and copper sputter coating finish to dissipate heat out of the top of the smart phone on a chip.

27. The computer program product of claim 21, wherein the code for causing a computer to apply a conformal coating to completely and thinly encase the one or more surface mounted additional components comprises code for causing a computer to apply a conformal coating that does not rise above the PCB laminate layers above the copper core more than the height of the tallest one or more surface mounted additional components.

28. The computer program product of claim 21, further comprising code for causing a computer to embed passive components in the copper core.

29. The computer program product of claim 21, further comprising:
a computer program product for making more than one smart phone on a chip, comprising code for causing a computer to:
embed a set of active components into one of multiple copper cores on a panel;
layer printed circuit board (PCB) laminate above and below each of the copper cores on the panel;
fix a copper ground plane underneath the layer of PCB laminate below, and furthest from, each of the copper cores on the panel;
surface mount one or more additional components on top of the PCB laminate layers above each of the copper cores on the panel; and
apply a conformal coating to completely and thinly encase the one or more surface mounted additional components on each of the copper cores, wherein the conformal coating includes trenching and a copper sputter coating finish.

30. The computer program product of claim 21, further comprising code for causing a computer to embed passive components into each of the copper cores on the panel.

31. The computer program product of claim 21, further comprising code for causing a computer to:
connect the smart phone on a chip to a main circuit board; and
assemble wireless devices that include the smart phone on a chip and the main circuit board.

32. A smart phone on a chip apparatus, comprising:
means for conducting heat from a copper core to dissipate heat out of the top and bottom of the smart phone on a chip, wherein active components are embedded in the copper core;
means for layering above and below the copper core, wherein one or more additional components are surface-mounted to the layering means above the copper core;
means for shielding the one or more additional components, wherein the shielding means is a conformal coating including trenching and a copper sputter coating finish; and
means for supporting the layering means below the copper core, wherein the supporting means is a copper ground plane.
